(19) United States
(12) Patent Application Publication
(10) Pub. No.: US 2008/0236748 A1
(43) Pub. Date: Oct. 2, 2008

(54) PLASMA PROCESSING APPARATUS

(76) Inventors: HIROYUKI KOBAYASHI, Kodaira (JP); Kenji Maeda, Sagamihara (JP); Kenetsu Yokogawa, Tsurugashima (JP); Masaru Izawa, Hino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/835,449

(22) Filed: Aug. 8, 2007

(30) Foreign Application Priority Data
Mar. 30, 2007 (JP) 2007-091809

(51) Int. Cl. H01L 21/306

(52) U.S. Cl. 156/345.27

(57) ABSTRACT

In a plasma processing apparatus including a processing chamber, a high-frequency power supply needed for plasma production, a unit that feeds a gas to the processing chamber, a shower plate, an exhausting unit that depressurizes the processing chamber, a stage on which a sample to be processed is placed, and a focus ring, the temperature of the focus ring can be regulated. A unit that measures a gas temperature distribution in the processing chamber is included. Based on the result of measurement of the gas temperature distribution, the temperature of the focus ring is controlled so that the gas temperature in the surface of the sample to be processed will be uniform.

### CLAIM OF PRIORITY

The present invention application claims priority from Japanese application JP2007-091809 filed on Mar. 30, 2007, the content of which is hereby incorporated by reference into this application.

### BACKGROUND OF THE INVENTION

1. Field of the Invention

The present invention relates to a plasma processing apparatus, or more particularly, to a plasma processing apparatus suitable for a semiconductor manufacturing system.

2. Description of the Related Art

In the process of manufacturing a semiconductor device such as a DRAM or a microprocessor, plasma etching or plasma chemical vapor deposition (CVD) is widely adopted. Critical elements in manufacturing of semiconductor devices using a plasma include issues of the uniformity of the process profiles, for example critical dimension, taper angle, or depth of hole or trench, across a sample (wafer) and a charging damage.

Now, the background of the invention will be described by taking etching for instance. FIG. 15 is an explanatory diagram concerning an etching mechanism that underlies etching to be performed on a SiOC film on a sample to be processed using a mixed gas composed of CHF₃, CF₄, and N₂ gases. The CF₄ and CHF₃ gases are dissociated in a plasma, whereby radicals of CF and CF₂ are produced. When the radicals enter the surface of the sample to be processed, they adhere to the surface of the sample to be processed at a certain probability. Consequently, a CF-system deposited film 92 is formed. Moreover, ions are generated in a plasma, and accelerated according to a method of, for example, supplying high-frequency bias power to the sample to be processed. Thus, the ions enter the surface of the sample to be processed.

When the incident energy of ions is applied to the interface between the deposited film 92 and SiOC film 90 (layer to be etched), the CF-system deposited film and layer to be etched chemically react to each other. Consequently, volatile gases of SiF₄ and CO gases are generated as by-products, and etching makes progress. When the deposited film gets too thick, before ions reach the interface between the layer to be etched and deposited film, the incident energy of ions is lost in the deposited film. This makes it hard to apply sufficient energy to the interface between the layer to be etched and deposited film. Consequently, etching reaction does not progress any more.

In contrast, when the deposited film is too thin, the deposited film that reacts to the layer to be etched lacks in carbon (C) or fluorine (F). This poses a problem in that an etching speed decreases. Further, even when the composition of the film is changed to contain quite a large amount of C, the progress of etching may be decelerated or ceased.

Nitrogen contained in a processing gas is used to regulate the thickness or composition of the deposited film. Nitrogen atoms dissociated from the nitrogen molecules in a plasma exert the effect of removing an excessively thick deposited film or removing excessive carbon from a deposited film in the form of CNx or the like.

Consequently, in order to uniformize the etched profiles (or processed profiles) across a sample to be processed, ions enter the sample to be processed have to be uniform in terms of a kind, a flux, and energy. Moreover, the thickness and composition of a film deposited on the surface of the sample to be processed, and the distribution of free radicals (including nitrogen and fluorine atoms) that determine the thickness and composition of the deposited film have to be uniform.

Japanese Patent Application Laid-Open Publication No. 2006-41088 has disclosed a method for bringing a deposited film to uniformity by feeding a processing gas, of which composition is changed between the vicinity of the center of a sample to be processed and the vicinity of the edge thereof, to a processing chamber.

Moreover, Japanese Patent Application Laid-Open Publication No. H07-310187 has disclosed an apparatus that includes a protective plate temperature regulating means for regulating the temperature of protective plates enclosing a sample that is processed in a plasma. The temperature of the protective plates is regulated to be retained at given certain temperature.

Further, WIPO Patent Publication No. WO 2004-085704 has disclosed a processing apparatus that measures the gas temperature through rotational temperature measurement and corrects the measured value of the density of each kind of free radical on the basis of the gas temperature.

### SUMMARY OF THE INVENTION

Methods for bringing the fluxes of ions, which enter a sample to be processed, to uniformity for the purpose of bringing the etched shapes in the surface of the sample to be processed to uniformity include, for example, a method of controlling the generation of a plasma using magnetic fields or the transportation of the plasma and a method of controlling a ratio of high-frequency power, which is supplied to the vicinity of the center of the sample to be processed in order to generate a plasma, to high-frequency power to be supplied to the vicinity of the perimeter thereof. For bringing a deposited film to uniformity, for example, a method of changing the composition of a feed gas or a method of regulating a temperature distribution in the surface of the sample to be processed so as to control the probability of adhesion of free radicals has been devised. However, etched shapes in a surface are requested to be further uniformity due to continuing scale down of the dimensions of the semiconductor device. A novel uniformity-of-etched shapes control means is needed.

By the way, when a current is generated in a sample to be processed for some reasons during etching and grows to a certain magnitude or more, transistors or the like formed in the sample to be processed are destroyed, that is, a so-called charging damage phenomenon takes place. One of causes of generation of a current in the sample to be processed is a difference in potential in a plasma between the center of the sample to be processed and the edge thereof. One of factors causing the potential in the surface of the sample to be processed in a plasma to vary is presumably the fact that the electron temperature in the plasma varies in the surface of the sample to be processed.

Along with the progressive tendency toward microscopic semiconductor devices, etched profiles are requested be more highly uniform in a surface in order to realize more microscopic semiconductor devices. However, plasma processing apparatuses not only have to meet the request but also have to avert occurrence of a charging damage.

The methods disclosed in the Japanese Patent Application Laid-Open Publications No. 2006-41088 and H07-310187 have difficulty in reliably averting the charging damage phenomenon. Moreover, the WIPO Patent Publication No. WO 2004-085704 does not taken account of the charging damage, though it has disclosed measurement of the rotational temperature of a gas.

An object of the present invention is to provide a plasma processing apparatus that can improve the uniformity among etched profiles in a sample to be processed by bringing an electron temperature distribution in a plasma to uniformity, and can minimize a charging damage.

A typical example of the configuration of a plasma processing apparatus in accordance with the present invention will be described below. Specifically, the plasma processing apparatus includes a processing chamber in which a sample to be processed is processed in a plasma, means for feeding a processing gas to the processing chamber, exhausting means for depressurizing the processing chamber, a high-frequency power supply for generating a plasma, and a sample placement electrode on which the sample to be processed is placed. The plasma processing apparatus further includes an ring-shaped member that is disposed on the perimeter of the sample placement electrode and has the temperature thereof regulated, means for measuring the gas temperature in the processing chamber, and an unit for controlling the regulation of the temperature of the ring-shaped member on the basis of a gas temperature distribution in the processing chamber obtained based on measured gas temperatures.

According to the present invention, etched profiles in the surface of a sample to be processed can be made uniform with numerous elements, which determine etched shapes and include a gas density, a radical density, an electron temperature, and an electron density, brought to higher uniformity. Thus, even more microscopic shapes can be readily etched uniformly. Further, the distribution of etched dimensions in the surface of the sample to be processed can be made uniform in the state with a uniformized electron temperature. Eventually, a charging damage can be minimized.

### BRIEF DESCRIPTION OF THE DRAWINGS

These and other features, objects and advantages of the present invention will become more apparent from the following description when taken in conjunction with the accompanying drawings wherein:

FIG. 1 is a schematic longitudinal sectional view showing a major portion of a plasma processing apparatus in accordance with the first embodiment of the present invention;

FIG. 2 is a schematic longitudinal sectional view of the plasma processing apparatus for use in explaining the other potion of the first embodiment that is not shown in FIG. 1;

FIG. 3 is a schematic view for use in explaining the perimeter of a stage included in the first embodiment;

FIG. 4A is an explanatory diagram concerning the structure of a shower plate included in the first embodiment and the deposition of condensing heads included therein;

FIG. 4B is an explanatory diagram concerning the arrangement of condensing holes for the condensing heads included in the first embodiment;

FIG. 5 is a block diagram showing the configuration of a control device included in the plasma processing apparatus in accordance with the first embodiment;

FIGS. 6A and 6B are explanatory diagrams concerning a method of evaluating the rotational temperature of a molecule;

FIG. 7 shows an example of results of measurement representing gas temperature distributions;

FIG. 8 is an explanatory diagram concerning the sizes of a focus ring and a shower plate;

FIG. 9 is an explanatory diagram concerning a control procedure for bringing machined dimensions in a wafer surface to uniformity according to the present invention;

FIG. 10A is an explanatory diagram showing a plasma radiation intensity distribution;

FIG. 10B is an explanatory diagram showing an example of a plasma density distribution;

FIG. 10C is an explanatory diagram showing an example of an electron temperature distribution;

FIG. 11A is an explanatory diagram showing an example of a gas temperature distribution;

FIG. 11B is an explanatory diagram showing an example of a gas density distribution;

FIG. 11C is an explanatory diagram showing an example of a distribution of densities of free radicals of each kind;

FIG. 12A is an explanatory diagram showing an example of a gas temperature distribution attained when the present invention is applied;

FIG. 12B is an explanatory diagram representing an example of a gas density distribution attained when the present invention is applied;

FIG. 12C is an explanatory diagram representing an example of a plasma density distribution attained when the present invention is applied;

FIG. 12D is an explanatory diagram representing a distribution of densities of free radicals of each kind attained when the present invention is applied;

FIG. 13 is an explanatory diagram showing the second embodiment of the present invention;

FIG. 14 is an explanatory diagram showing the third embodiment of the present invention; and

FIG. 15 is an explanatory diagram concerning an etching mechanism.

### DETAILED DESCRIPTION OF THE PREFERRED EMBODIMENTS

According to a typical embodiment of the present invention, in a plasma processing apparatus including a processing chamber, a high-frequency power supply needed to generate a plasma, means for feeding a gas to the processing chamber, a shower plate, exhausting means for depressurizing the processing chamber, a stage on which a sample to be processed is placed, and a focus ring, a helium gas for use in cooling is fed to the back of the focus ring in order to regulate the temperature of the focus ring using the pressure of the helium gas. The plasma processing apparatus further includes means for measuring a gas temperature distribution in the processing chamber, and an unit for controlling the regulation of the temperature of the ring-shaped member based on the measured gas temperature distribution. Based on the result of measurement of the gas temperature distribution, the temperature of the focus ring is controlled so that the gas temperature in the surface of the sample to be processed will be uniform. Further, the diameter of the shower plate and the width of the focus ring are increased. Moreover, since the temperature of the focus ring can be regulated, the gas temperature in the processing chamber can be made uniform.

The embodiments of the present invention will be described below in conjunction with the drawings.

### First Embodiment

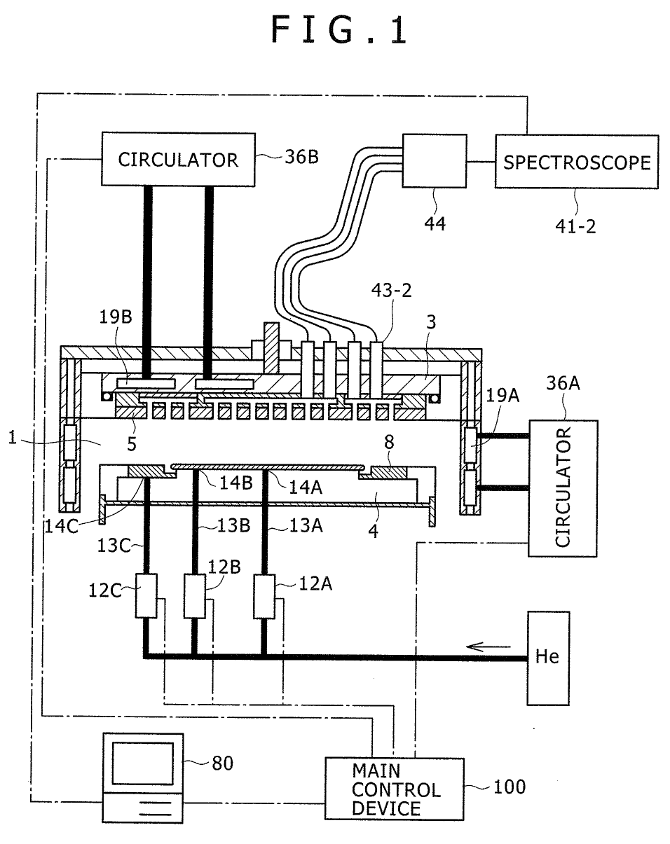

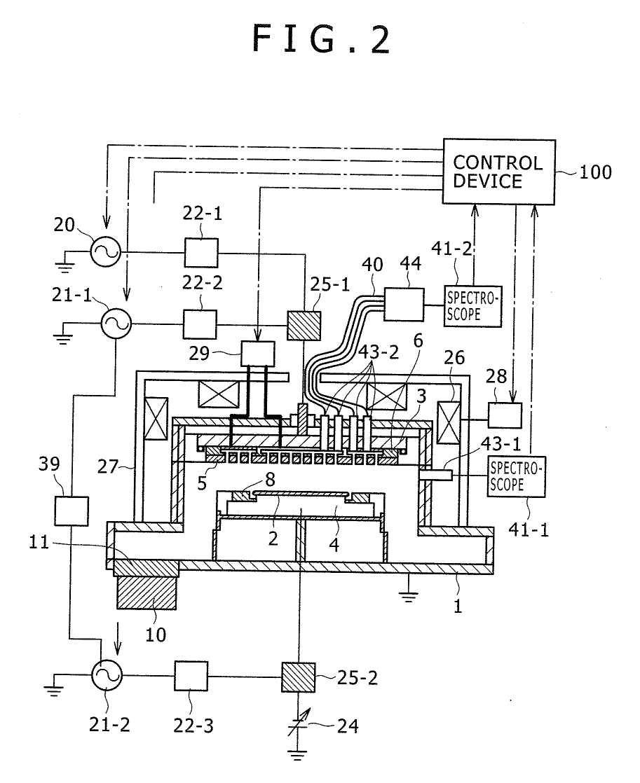

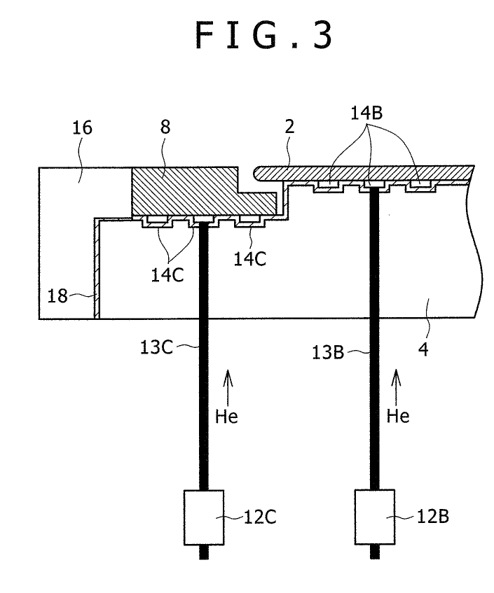

To begin with, the first embodiment of the present invention will be described with reference to FIG. 1 to FIG. 12. FIG. 1 and FIG. 2 show an example of a parallel plate type ultrahigh-frequency electron cyclotron resonance (UHF-ECR) plasma processing apparatus. FIG. 2 is centered on a portion of the plasma processing apparatus that controls a gas temperature distribution. FIG. 1 schematically shows the apparatus while being centered on the other portion that is not shown in FIG. 2. FIG. 3 shows the perimeter of a stage.

A processing chamber 1 has a stage (a sample placement electrode) 4. A ring-shaped member (a focus ring) 8 made of a silicon is placed on the perimeter of the portion of the stage 4 on which a sample to be processed 2 is placed. The ring-shaped member 8 has the temperature thereof regulated as described later.

A passage 19A through which a coolant serving as a cooling means circulates is formed in the insides of the sidewalls of the processing chamber 1. An insulating coolant whose temperature is regulated is fed to the passage through a circulator 36A. In order to suppress a rise in the temperature of a shower plate 5, an insulating coolant whose temperature is regulated is fed to a passage 19B, which is formed in an antenna 3 and through which the coolant circulates, through a circulator 36B. The temperature of the antenna is thus regulated in order to regulate the temperature of a gas dispersion plate disposed under the antenna. The heat transfer between the gas dispersion plate and shower plate is utilized in order to regulate the temperature of the shower plate. Moreover, a passage (not shown) through which an insulating coolant such as Fluorinert (registered Trademark) flows is disposed below the stage 4 for the purpose of temperature regulation (cooling). The temperature of the coolant is controlled to be lower than the temperature regarded as a target of control extended to the sample to be processed.

Further, a helium gas can be fed to the back of a sample to be processed in order to cool the sample to be processed on the stage 4. Moreover, a gas line 13A through which the helium bas is fed to a gas channel 14A led to on the internal part of the back of the sample to be processed, and a gas line 13B through which the helium gas is fed to a gas channel 14B led to the perimeter of the back of the sample to be processed are included so that the temperature of the internal part of the sample to be processed and the temperature of the perimeter thereof can be regulated independently of each other. Further, a gas channel 14C is formed in the focus ring placement surface of the stage 4 so that the helium gas can be fed to the back of the focus ring. A gas line 13C is coupled to the gas channel 14C in order to feed the helium gas to the gas channel 14C.

Moreover, mass flow controllers 12 (A, B, and C) are disposed on the respective helium gas lines 13 (A, B, and C) so that flow rates at which a helium gas is fed to the internal part of a sample to be processed, the perimeter thereof, and the back of the focus ring respectively can be controlled independently of each other. The mass flow controllers 12 are controlled by a main control device 100.

In the present apparatus, light emitted from a plasma (emission from plasma) is gathered sideways by a condensing head 43-1, and the spectrum thereof is measured by a spectroscope 41-1. Light emitted from the plasma and gathered by condensing heads 43-2 is measured by a spectroscope 41-2. The results of the measurements are used to obtain a gas temperature distribution in the processing chamber at a terminal 80. The data is sent to the main control device 100.

A DC power supply 24 is connected to the stage 4 via a filter 25-2 in order to fix a sample to be processed and the focus ring 8 to the stage 4 by utilizing electrostatic adsorption. The base material of the stage 4 is aluminum, and a sprayed coating 18 is formed on the base material with alumina or yttria.

The antenna 3 through which electromagnetic waves are radiated is disposed in parallel with the stage 4, on which the sample to be processed 2 is placed, in the upper part of the processing chamber 1. A high-frequency source power supply 20 needed to generate a plasma is connected to the antenna 3 via a matching box 22-1 and a filter 25-1. A bias power supply 21-1 that supplies high-frequency bias power is connected to the antenna via a matching box 22-2 and the filter 25-1. The filter 25-1 is intended not to allow high-frequency power, which is used to generate a plasma, to flow into the bias high-frequency power supply 21-1 connected to the antenna, and not to allow high-frequency bias power to flow into the source power supply 20 that is needed to generate a plasma and connected to the antenna. A bias power supply 21-2 is connected to the stage 4 via a matching box 22-3 and a filter 25-2 in order to accelerate ions that impinge into the sample to be processed 2.

The shower plate 5 is disposed below the antenna 3 with a dispersion plate 6 between them. A processing gas fed from a processing gas source 29 is dispersed by the gas dispersion plate, and fed to the processing chamber through gas holes formed in the shower plate.

Solenoid coils 26 and yokes 27 are disposed outside the processing chamber in order to produce magnetic fields in the processing chamber. The solenoid coils 26 are designed so that a magnetic field strength or a distribution of magnetic fields (directions of lines of magnetic force) can be controlled by a magnetic field control device 28.

A plasma is efficiently generated in the processing chamber 1 through electron cyclotron resonance based on interaction of high-frequency power, which is used to generate a plasma and radiated through the antenna 3, with magnetic fields. Moreover, since the magnetic field control device 28 controls the magnetic field strength or magnetic field distribution, a plasma density distribution of a generated plasma and the transportation thereof can be controlled. Consequently, the uniformity in the plasma density distribution can be controlled.

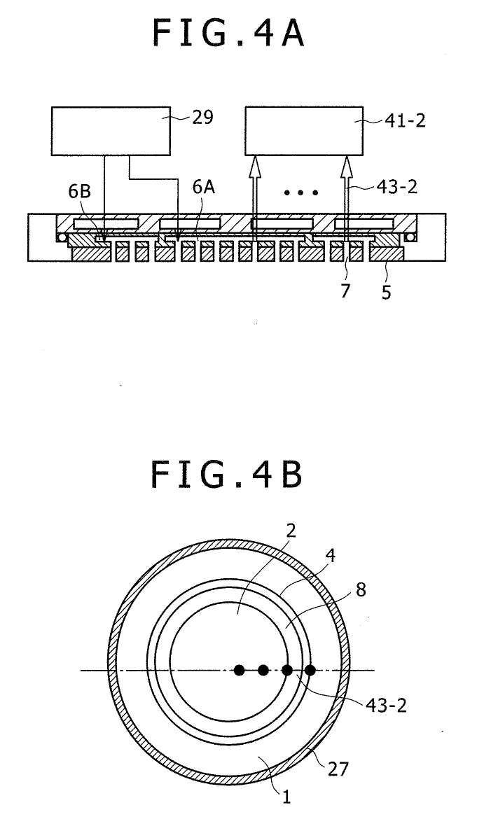

Incidentally, as shown in FIG. 4A, the gas dispersion plate 6 is divided into two regions 6A and 6B that are radially internal and external regions. This is intended to control the flow rate and composition of a gas to be fed from the processing gas source 29 to the vicinity of the center of a sample to be processed independently of those of the gas to be fed therefrom to the vicinity of the perimeter of the sample to be processed, so that the etched profiles in the surface of the sample to be processed can be made uniform. As for concrete examples of the components of the processing gas source 29, for example, a gas flow rate regulator and a distributor disclosed in the Japanese Patent Application Laid-Open Publication No. 2006-41088 are employed.

The sidewalls of the processing chamber 1 are grounded. Moreover, exhausting means 10 such as a turbo molecular pump intended to depressurize the processing chamber is attached to the processing chamber 1 via a butterfly valve 1.

High-frequency bias power to be supplied to the stage 4 and high-frequency bias power to be supplied to the antenna 3 shall have the same frequency. A phase controller 23 controls a phase difference between the high-frequency bias power to be supplied to the antenna 3 and the high-frequency bias power to be supplied to the stage 4. When the phase difference is 180°, confinement of a plasma improves. The flux of ions incident on any of the sidewalls of the processing chamber 1 (the number of incident ions per unit time or unit area) or the energy thereof decreases. Consequently, the number of foreign matters derived from wasting of the sidewalls can be decreased, or the service life of the coating on the material made into the sidewalls can be extended.

As shown in FIG. 4A, the multiple condensing heads 43-2 gather light emitted from a plasma through the holes in the shower plate so that a plasma radiation distribution in a radial direction of a sample to be processed can be measured and a gas temperature distribution or a plasma density distribution can be obtained from the result of the measurement. The rotational temperature of the gas in the processing chamber is calculated through the gas temperature measurement, and the temperature range in the processing chamber is decided based on the rotational temperature. As for the holes through which the respective condensing heads 43-2 gather light, holes dedicated to gathering of light are, as shown in FIG. 4B, formed at positions corresponding to the positions of some of the numerous gas holes 7 formed in the shower plate 5. Incidentally, pieces of information obtained by the multiple condensing heads 43-2 respectively are used to measure a radical radiation intensity distribution across a sample to be processed.

Plasma light (emission from plasma) gathered by the condensing heads 43-2 respectively are transferred over optical fibers, and the spectra thereof are measured by the spectroscope 41-2. Since the light (emission from plasma) gathered by the condensing heads 43-2 respectively are transferred over the respective fibers, for example, a multiplexer 44 is used to switch channels so as to select a channel to be measured. The light on the selected channel is transferred to the spectroscope. Needless to say, the multiplexer may not be employed. Instead, a method according to which the optical fibers are juxtaposed in order to measure the light so that a two-dimensional image representing the channels in one dimension and wavelengths in the other dimension can be formed on a CCD included in the spectroscope. Moreover, the spectroscope 41-1 should preferably be able to measure light over a wide range of wavelengths, though it may be able to offer a wavelength resolution of 1 nm or more, that is, it may not be very precise. However, the spectroscope 41-2 to be used to measure gas temperature should preferably be able to offer a high wavelength resolution of 1 nm or less (for example, 0.1 nm).

Data items measured by the spectroscopes 41-1 and 41-2 are sent to the main control device 100. Based on the resultant data items, the mass flow controllers 12, source power supply 20, bias power supply 21, magnetic field control device 28, processing gas source 29, circulators 36, and phase controller 39 are controlled.

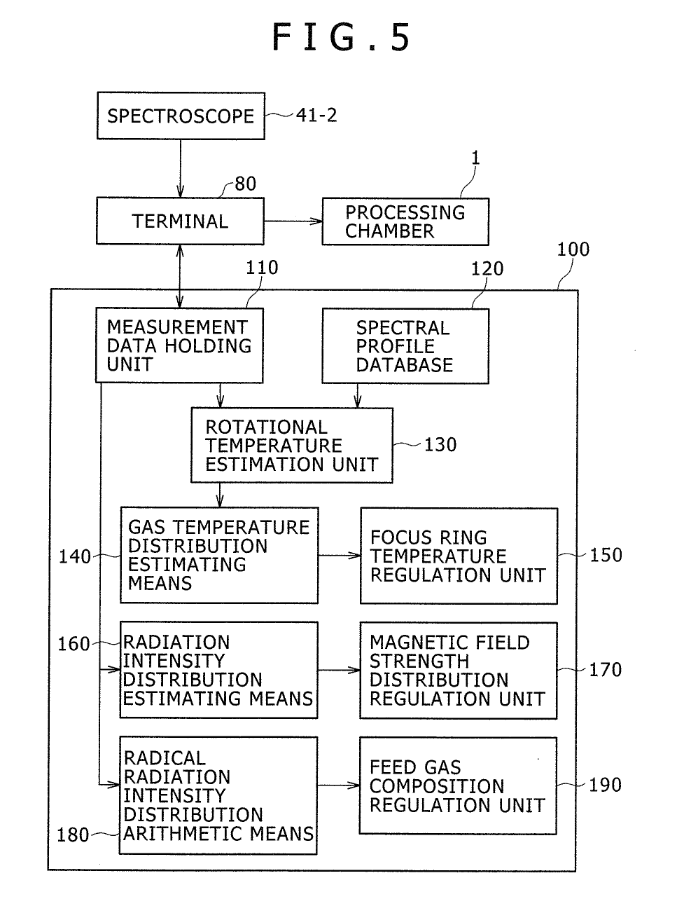

FIG. 5 is a block diagram showing the control device 100 included in the plasma processing apparatus. The control device 100 includes a measurement data holding unit 110 that holds in memory measurement data items to be plotted into a spectral profile representing the spectrum in the processing chamber 1 measured by the spectroscopes 41-1 and 41-2, a spectral profile database 120 in which data items plotted into the spectral profiles and associated with each of multiple rotational temperatures of molecules are held in association with each gas whose rotational temperatures are calculated in advance, and a rotational temperature estimation unit 130 that estimates the rotational temperatures of gas molecules through comparison of the measured values plotted into the spectral profile with the data items plotted into the spectral profile.

The control device 100 further includes: a gas temperature distribution estimating means 140 for estimating the distribution of gas temperatures in the processing chamber on the basis of the estimated rotational temperatures of gas molecules; a focus ring temperature regulation unit 150 that regulates the temperature of the focus ring on the basis of the estimated gas temperature distribution; a plasma radiation intensity distribution estimating means 160 for estimating the distribution of radiation intensities in the processing chamber on the basis of data items of measured plasma radiation intensities; a magnetic field strength distribution regulation unit 170 that regulates the distribution of magnetic field strengths in the processing chamber by controlling the magnetic field control device 28 on the basis of the obtained radiation intensity distribution; a radical radiation intensity distribution arithmetic means 180 for obtaining the distribution of radical radiation intensities in the processing chamber on the basis of data items of measured plasma radiation intensities; and a feed gas composition regulation unit 190 that regulates the composition of a processing gas to be fed to the processing chamber by controlling the processing gas source 29 on the basis of the obtained radical radiation intensity distribution.

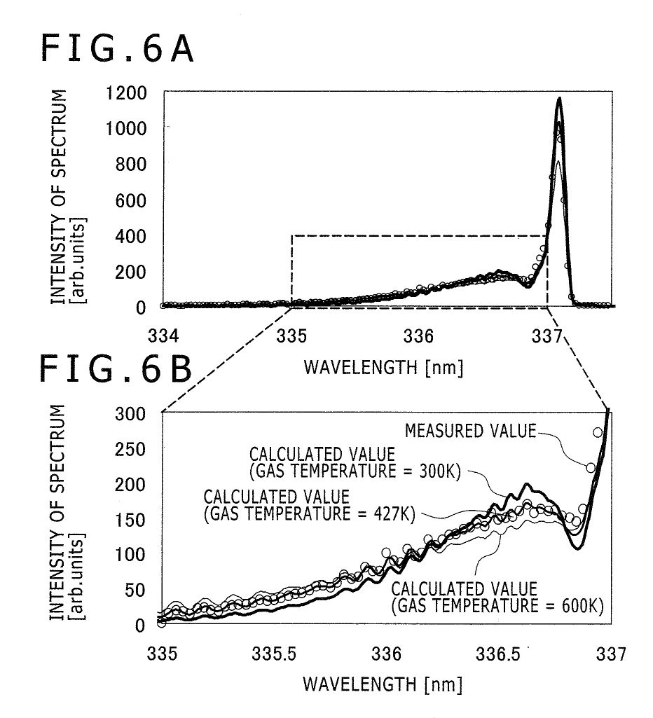

Next, a method of calculating a rotational temperature to be used to estimate a gas temperature will be described below. FIGS. 6A and 6B show an example of comparison of calculated values plotted into a spectral profile in relation with nitrogen molecules (values held in the spectral profile database 120) with measured values (values in the measurement data holding unit 110). A mixed gas of a nitrogen gas and a CF₄ gas is adopted as a discharge gas. In FIG. 6A, wavelengths range from 334 nm to 338 nm. FIG. 6B shows in enlargement the range of wavelengths from 335 nm to 337 nm shown in FIG. 6A. A circle indicates a measured value. A calculated value is obtained by presuming the rotational temperatures of nitrogen molecules to be specific values. The rotational temperatures are supposed to be 300 K (indicated with a bold line), 427 K (indicated with a moderate line), and 600 K (indicated with a thin line).

As seen from FIGS. 6A and 6B, the profile representing a spectrum varies depending on the rotational temperature of nitrogen molecules. In the examples shown in FIGS. 6A and 6B, a measured spectral profile is highly consistent with the calculated values plotted into a spectral profile on the assumption that the rotational temperature is 427 K. The rotational temperature estimation unit 130 included in the control device 100 compares the measured spectral profile with spectral profiles resulting from calculation, and searches the rotational temperature causing the calculated spectral profile to be most highly consistent with (best fitted to) the measured spectral profile. Thus, the rotational temperature of molecules (herein 427 K) is obtained. The obtained rotational temperature of molecules can be regarded as the temperature of a gas in the background.

When a rare gas is added, the absolute value of the temperature of a gas in the background and the absolute value of the rotational temperature of molecules often have a difference. However, whether the gas temperature is uniform can be decided based on values measured for detecting a gas temperature distribution.

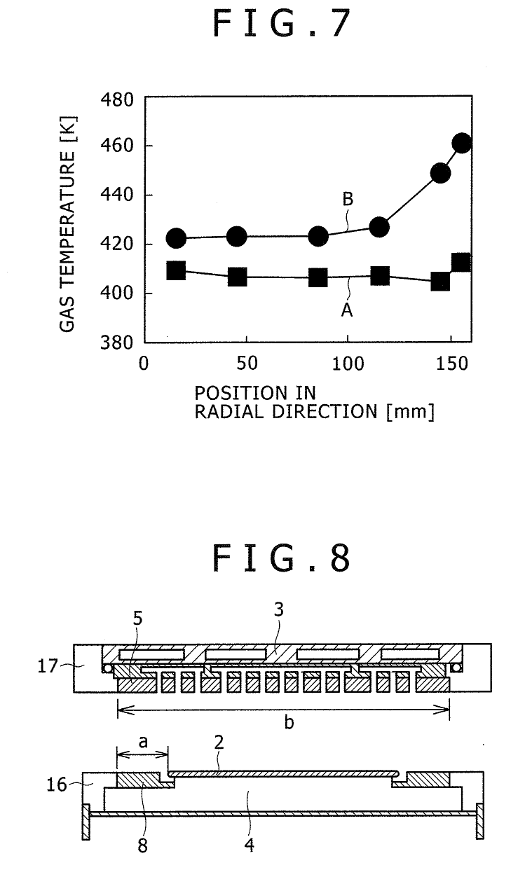

FIG. 7 shows an example of results of measurement of a gas temperature distribution. A gas temperature distribution A shown in FIG. 7 is plotted based on the results of measurement performed in a situation in which the temperatures of parts, that is, the focus ring 8 and a susceptor 16 are low. A gas temperature distribution B is an example of a gas temperature distribution obtained when the temperatures of the focus ring and susceptor are not regulated but heated due to a plasma. The temperature of the focus ring is actually measured to rise up to about 200° C. In contrast, the temperature in the surface of a sample to be processed remains uniform at about 60° C. due to cooling achieved with helium fed to the back of the sample to be processed. Moreover, the temperature distribution in the shower plate is nearly uniform owing to cooling achieved with a processing gas that flows between the shower plate and gas dispersion plate. Consequently, the temperature distribution B shown in FIG. 7 demonstrates that the high gas temperature on the perimeter of the sample to be processed is derived from a rise in the temperature of the focus ring disposed immediately adjacently to the sample to be processed. When the temperature of the focus ring rises, the gas temperature in the vicinity of the focus ring rises. The adverse effect of the rise is observed even at a position separated by about 50 mm from the perimeter of the sample to be processed. In particular, the adverse effect of the rise is significant in a range extending internally by about 30 mm from the perimeter of the sample to be processed. Assuming that the temperature of the focus ring is regulated to be substantially equal to the temperature of the sample to be processed, when the width of the focus ring is, for example, 20 mm and the susceptor disposed outside the focus ring is devoid of a cooling mechanism, the adverse effect of heating of a gas by the susceptor is observed even in an internal region separated by about 3 cm from the perimeter of the sample to be processed.

Consequently, the sizes of the focus ring and shower plate have significant meanings. This will be described in conjunction with FIG. 8. In FIG. 8, reference sign a denotes the width of the focus ring, and is preferably equal to or larger than 3 cm or set to, for example, 5 cm. However, when measures are taken to prevent the temperature of the susceptor from getting higher due to heating of a plasma, the width of the focus ring may be smaller than 5 cm. Moreover, even when the focus ring cannot be designed to be large in size by reason that the inner diameter of the processing chamber is not very large, the width of the focus ring should preferably be set to 3 cm or more.

Moreover, in FIG. 8, reference sign b denotes the diameter of the shower plate or the diameter of a bare part of the shower plate. The diameter is larger than the diameter of a sample to be processed by at least a double of 30 mm. Specifically, when the diameter of the sample to be processed is 300 mm, the diameter of the shower plate or the bare part of the shower plate should preferably be equal to or larger than about 360 mm. Further, when no restrictions are imposed on, for example, the inner diameter of the processing chamber, the diameter of the shower plate should preferably be equal to or larger than 400 mm. However, when a quartz ring or the like disposed outside the focus ring is provided with a cooling feature or the like, the diameter of the shower plate may be smaller than the above value.

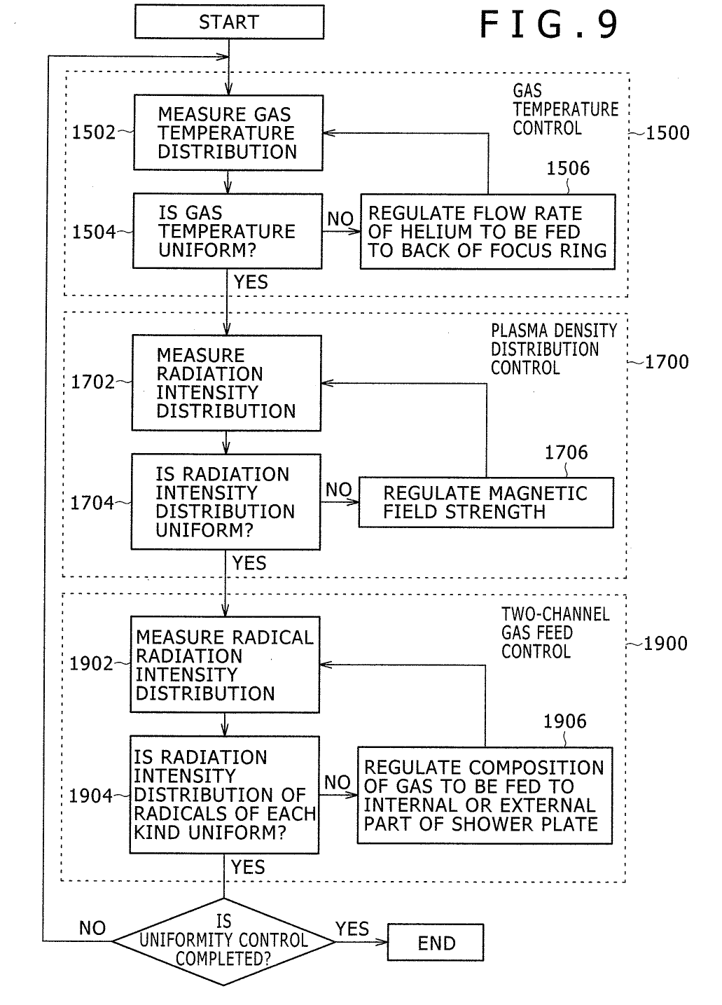

Next, referring to FIG. 9 to FIG. 12, an example of a method of bringing machined dimensions in the surface of a sample to be processed to uniformity according to the present embodiment will be described below.

FIG. 9 shows an example of a uniformity control flow to be followed so that the conditions for etching, which is performed on a sample to be processed by the plasma processing apparatus in accordance with the present embodiment, can be made uniform. In an initial state, a gas temperature distribution is not uniform. However, assume that etched profiles in the surface of the sample to be processed are generally uniform owing to a plasma distribution control feature (1700) utilizing magnetic fields and a two-channel gas feed feature (1900).

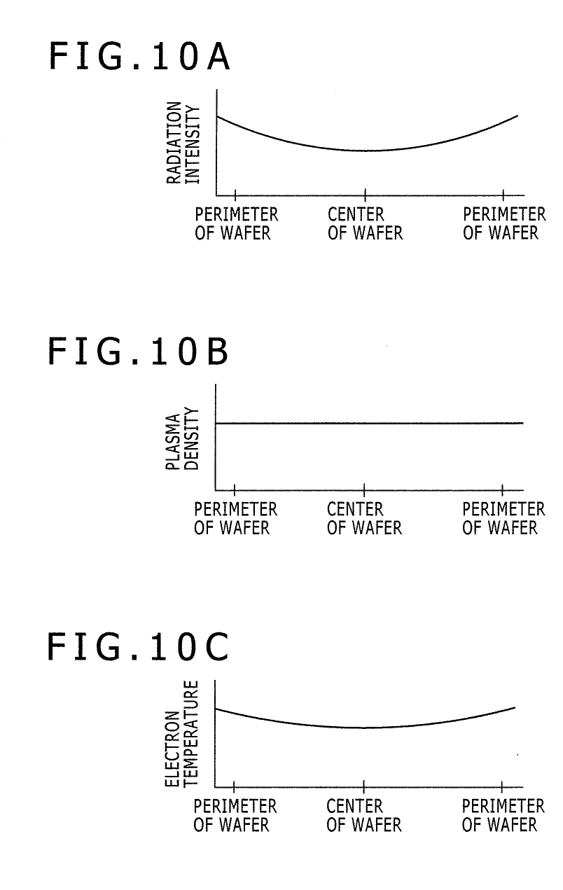

In this case, when a plasma radiation intensity distribution is measured, an integrated value of radiation intensities detected on the perimeter of a sample (wafer) to be processed or slightly outside the sample to be processed over a wide range of wavelengths may be, as shown in FIG. 10A, generally larger. The radiation intensity is simply thought to depend on a product of a gas density by an electron temperature by an electron density. A major factor causing the radiation intensity to get larger in the vicinity of the perimeter of the sample to be processed is thought to be a possibility that a plasma density (which shall herein refer to the electron density or an ion density) is larger in the vicinity of the perimeter of the sample to be processed or a possibility that the electron temperature is higher in the vicinity of the perimeter of the sample to be processed (the gas density is, as described later, smaller on the perimeter of the sample to be processed). When the uniformity in etched shapes in the surface of the sample to be processed is high, a distribution of ion fluxes in the surface of the sample to be processed is thought to be generally uniform. Consequently, the distribution of ion densities, that is, plasma densities is, as shown in FIG. 10B, predicted to be generally uniform in the surface of the sample to be processed. The major factor causing the radiation intensity to get higher in the vicinity of the perimeter of the sample to be processed is thought to be the fact that the electron temperature is, as shown in FIG. 10C, higher in the vicinity of the perimeter of the sample to be processed.

On the other hand, simply speaking, the density of a free radical is thought to be determined with a product of an electron density by an electron temperature by a density of a gas from which the free radical is produced. As long as the electron temperature is not uniform, the radical density is not uniform. Consequently, there is a fear that the uniformity in etched profiles in the surface of a sample to be processed may be broken up. A reason why although the electron temperature is not uniform as shown in FIG. 10C, dimensions of etched profiles in the surface of the sample to be processed are uniform will be described below.

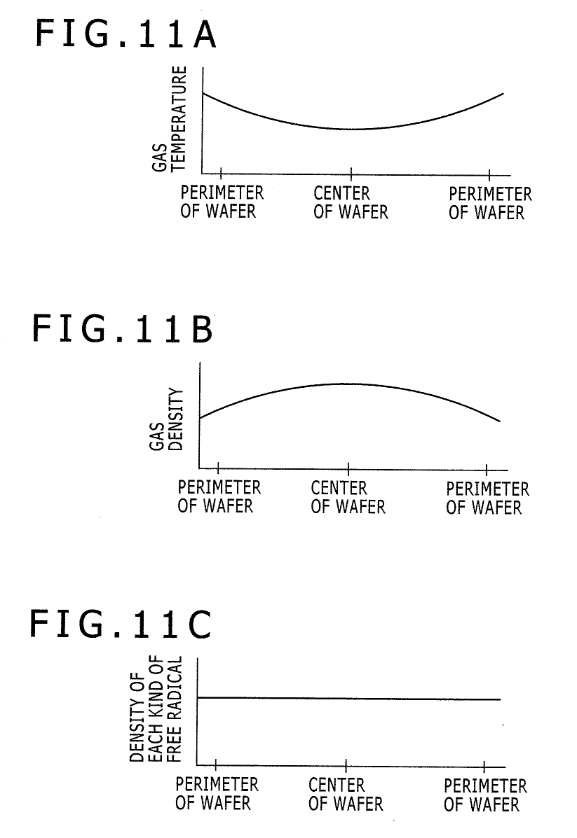

FIG. 11A shows the results of measurement of a rotational temperature distribution of nitrogen molecules existing immediately above a sample to be processed as well as slightly outside the sample to be processed. The rotational temperature of a nitrogen gas added to a processing gas may be regarded as being equal to the temperature of the background gas under a certain condition that a rare gas such as argon is not added. FIG. 11A shows the distribution of gas temperatures. The gas temperature on the perimeter of the sample to be processed is higher. Since the pressure of a gas in the processing chamber is generally uniform, the pressure of the gas in the surface of the sample to be processed is nearly uniform. Although the pressure of the gas is nearly uniform, if the gas temperature in the processing chamber is not uniform, the gas density distribution is not uniform. This is attributable to a relational expression “gas density a gas pressure/gas temperature.” Namely, the gas density gets lower in the vicinity of the perimeter of the sample to be processed in which the gas temperature is high.

As already described, a radical density is simply thought to depend on a product of an electron density by an electron temperature by a gas density. Therefore, when a gas density distribution is not uniform, it is highly possible that a density distribution of free radicals is not uniform. However, in the vicinity of the perimeter of a sample to be processed in which a gas density is lower as shown in FIG. 11B, the electron temperature is, as shown in FIG. 10C, higher. Consequently, the uniformity in a radical density distribution is thought to be, as shown in FIG. 11C, attained because the non-uniformity in a gas temperature and the non-uniformity in the electron temperature are compensated each other.

However, the non-uniformity in an electron temperature distribution shown in FIG. 10C is likely to cause a charging damage. Therefore, the electron temperature is preferably uniform. Moreover, along with the continuing scale down of the dimensions of the semiconductor device, etched profiles in the surface of a sample to be processed will be severely requested to exhibit uniformity. A method of compensating the non-uniformity in a certain element by the non-uniformity in another element so that machined shapes in the surface of a sample to be processed will be made uniform will apparently reach its limit.

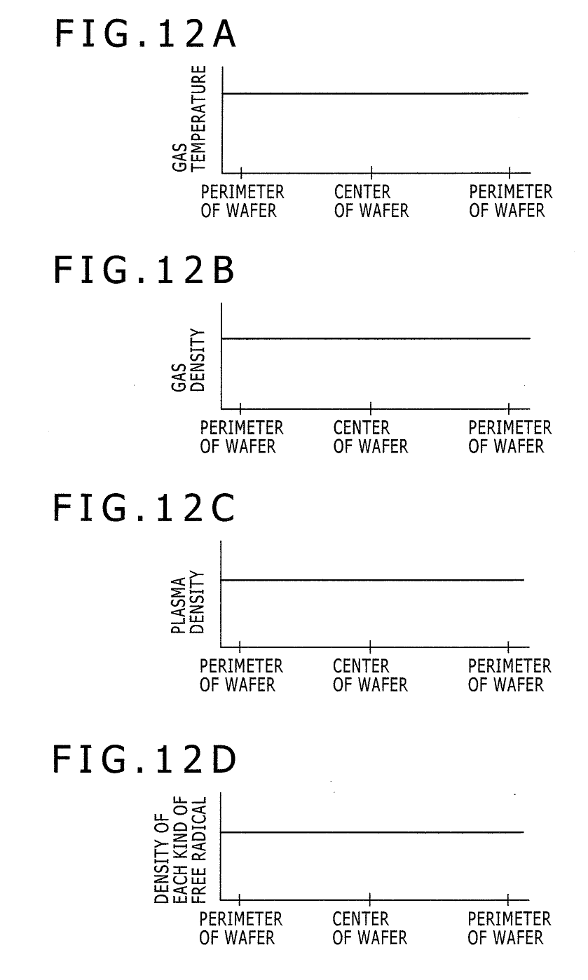

In the present embodiment, first, the temperature of the focus ring is regulated (1500) by a focus ring temperature regulation unit 150. Herein, a gas temperature distribution is measured. If the gas temperature distribution is not uniform, the pressure of a helium gas to be fed to the back of the focus ring is modified so that the gas temperature will be uniform. First, the gas temperature distribution estimating means 140 estimates a gas temperature distribution on the basis of the estimated values of the rotational temperatures of gas molecules obtained by the rotational temperature estimation unit 130 (1502). Thereafter, a decision is made on whether a gas temperature distribution is uniform across a sample to be processed (1504). If the gas temperature distribution is not uniform, the focus ring temperature regulation unit 150 regulates the flow rate of a helium gas to be fed to the back of the focus ring so that the gas temperature distribution will be, as shown in FIG. 12A, uniform (1506). Consequently, a gas density distribution becomes, as shown in FIG. 12B, uniform. However, in this stage, an electron temperature distribution is still not uniform as shown in FIG. 10C. Therefore, an ion flux distribution is also not uniform similarly to the electron temperature distribution shown in FIG. 10C.

Thereafter, if the gas temperature distribution is uniform within a predetermined range, control is passed to step 1700 of plasma density distribution control. Herein, a plasma density distribution is estimated based on a distribution of radiation intensities. If the plasma density distribution is not uniform, magnetic field strength is regulated so that the plasma density distribution will be uniform. In other words, the radiation intensity distribution arithmetic means 160 estimates a radiation intensity distribution in the processing chamber on the basis of data items of the radiation intensities of a plasma (1702). A decision is made on whether the radiation intensity distribution is uniform in the surface of a sample to be processed (1704). If the plasma radiation intensity distribution is not uniform, the magnetic field strength distribution regulation unit 170 regulates a magnetic field strength distribution in the processing chamber so that the plasma density distribution will be uniform as shown in FIG. 12C (1706).

In this state, a two-channel gas feeding system is still established so that a radical density distribution will be uniform although an electron temperature distribution or a gas density distribution is not uniform. Thereafter, when the electron temperature or an electron density is made uniform, there is a fear that the radical density distribution may not be uniform. Therefore, control is passed to step 1900 of two-channel gas feed control. Herein, a density distribution of free radicals or atoms of each kind is calculated based on a radiation intensity distribution relevant to each wavelength at which free radicals of each kind are generated (1902). A decision is made on whether the radiation intensity distribution of free radicals of each kind is uniform in the surface of a sample to be processed (1904). If the radiation intensity distribution is not uniform, the feed gas composition regulation unit 190 regulates the composition of a processing gas to be fed to the internal or external part (6A or 6B) of the shower plate so that the radiation intensities of free radicals of each kind will be uniform. Consequently, the density distribution of free radicals of each kind is made uniform (1906). A gas temperature distribution, a plasma density distribution, and a radical density distribution are checked. If the distributions are uniform within respective predetermined ranges of values, uniformity control is terminated.

In the example shown in FIG. 9, a gas temperature distribution, a plasma density distribution, and a radical density distribution are regulated in that order. They need not always be regulated in that order. For example, among the gas temperature distribution, plasma density distribution, and radical density distribution, the distribution whose uniformity is lowest may be regulated as a top priority.

Next, a description will be made of a method of controlling a gas temperature distribution using a focus ring temperature regulation feature. The terminal 80 uses emission from plasma gathered by the condensing heads 43-2 to obtain a gas temperature distribution in the processing chamber. If the gas temperature on the perimeter of a sample to be processed is larger than the gas temperature in the vicinity of the center thereof, the mass flow controllers 12 increase the pressure of a helium gas to be fed to the back 14C of the focus ring so that the temperature of the focus ring 8 will be lowered. In contrast, if the gas temperature on the perimeter of the sample to be processed is smaller, the flow rate of the helium gas to be fed to the back of the focus ring is decreased in order to increase the temperature of the focus ring. When the channel 19A for a coolant to be used to regulate the temperature of the internal walls of the processing chamber is formed in the sidewalls of the processing chamber 1, the temperature of the coolant that flows through the channel may be regulated using the circulator 36. When the temperature of the internal walls of the processing chamber can be regulated using a heater or the like, the temperature set on the heater may be regulated.

Incidentally, instead of the focus ring that is a ring-shaped member, a member that is disposed at a position on the stage consistent with the position of the perimeter of a sample to be processed and that has the temperature thereof regulated, for example, a susceptor or an electrode cover to be disposed outside the focus ring may be provided with the same temperature regulation feature as the temperature regulation feature of the focus ring.

According to the present embodiment, the control device 100 controls the etching apparatus so that the gas temperature, plasma radiation intensity, and radiation intensity of each kind of radicals become uniform across a sample to be processed. When the sample to be processed is etched in this state, etched profiles of microscopic semiconductor devices become highly uniform in the surface of the sample to be processed. Moreover, occurrence of a charging damage is suppressed.

As mentioned above, according to the present embodiment, the elements determining etched shapes, such as, the electron temperature, electron density, gas density, and radical density are controlled to be uniform instead of compensating the non-uniformity in a specific element by the non-uniformity in another element. Consequently, etched profiles of microscopic semiconductor devices become uniform in the surface of a sample to be processed. Moreover, occurrence of a charging damage is suppressed.

### Second Embodiment

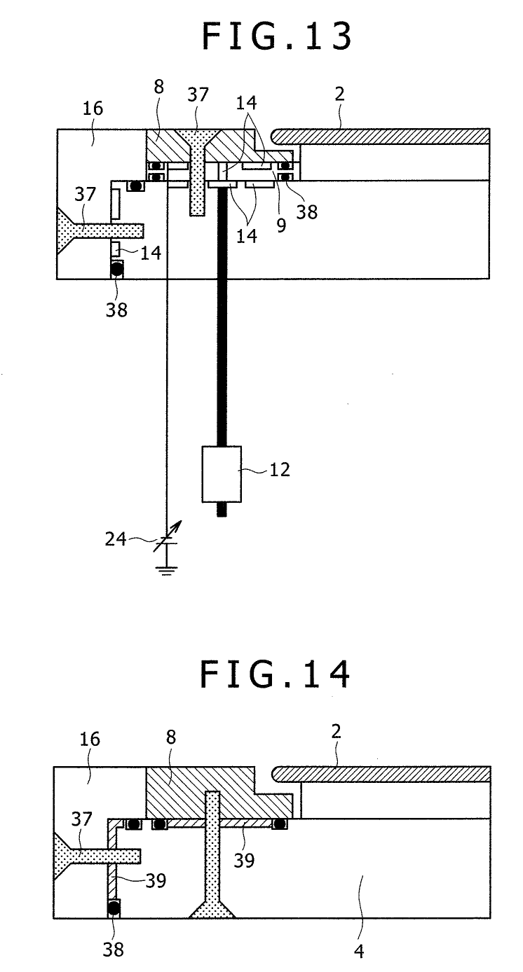

The second embodiment of the present invention will be described in conjunction with FIG. 13. FIG. 13 shows the perimeter of a type of stage that has a spacer 9 made of quartz or the like inserted into a space between the back of a focus ring 8 and the stage, and its surroundings. In this case, it is hard to fix the focus ring to the stage by utilizing electrostatic adsorption. The spacer 9 and focus ring 8 are therefore screwed to the stage 4. The spacer 9 has a gas channel that penetrates trough the spacer to link the back thereof and the face thereof, whereby a helium gas to be used for cooling can be fed to the gap between the focus ring and spacer and the gap between the spacer and stage. Moreover, especially when the width of the focus ring is smaller than 30 mm, a rise in the temperature of a susceptor has to be prevented for fear the gas temperature on the perimeter of a wafer may rise. The helium gas can therefore be fed to the gap between the susceptor, which is disposed outside the focus ring, and the stage. Preferably, an O-ring should be used to prevent leakage of a gas in order to maintain a high pressure using the helium gas to be fed at a low flow rate. Moreover, DC power or the like should preferably be supplied in order to regulate the potential on the focus ring.

Even in the present embodiment, a gas temperature distribution and other elements determining etched shapes are made uniform in the surface of a sample to be processed. Consequently, the uniformity among etched profiles in the surface of the sample to be processed can be improved and a charging damage can be minimized.

### Third Embodiment

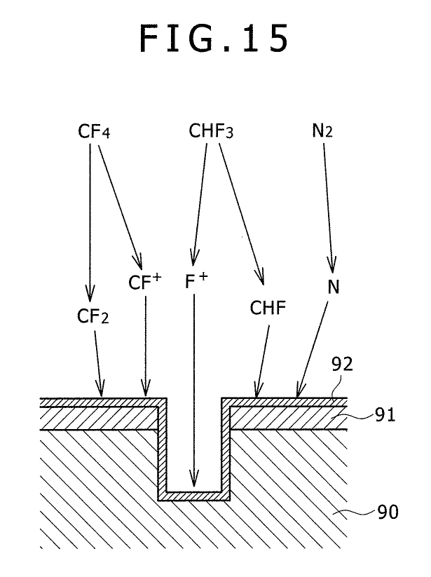

The third embodiment of the present invention will be described in conjunction with FIG. 14. FIG. 14 shows the perimeter of a stage and its surrounding in a case where a gas to be used for cooling is not fed to the back of a focus ring. In the present embodiment, a lubricant is poured into the gap between the focus ring and stage in place of the gas. An O-ring is disposed and fixed with a screw for fear the lubricant may leak out. The same applies to cooling of a susceptor.

Even in the present embodiment, a gas temperature distribution and other elements determining etched shapes are made uniform in the surface of a sample to be processed. Consequently, the uniformity among machined shapes in the surface of the sample to be processed can be improved, and a charging damage can be minimized.

What is claimed is:

1. A plasma processing apparatus comprising: a processing chamber in which a sample to be processed is processed in a plasma; means for feeding a processing gas to the processing chamber; exhausting means for depressurizing the processing chamber; a high-frequency power supply for plasma generation; and a sample placement electrode on which the sample to be processed is placed, the plasma processing apparatus further comprising:
a ring-shaped member that is disposed on the perimeter of the sample placement electrode and has the temperature thereof regulated;
means for measuring the gas temperature in the processing chamber; and
an unit for controlling regulation of the temperature of the ring-shaped member on the basis of a gas temperature distribution in the processing chamber obtained from measured gas temperatures.

2. A plasma processing apparatus comprising: a processing chamber in which a sample to be processed is processed in a plasma; gas feeding means for feeding a processing gas to the processing chamber; exhausting means for depressurizing the processing chamber; a high-frequency power supply for plasma production; a sample placement electrode on which the sample to be processed is placed; and an upper electrode opposed to the sample placement electrode, the gas feeding means including a shower plate disposed on the upper electrode,
the plasma processing apparatus further comprising:
a ring-shaped member that is disposed on the perimeter of the sample placement electrode and has the temperature thereof regulated;
means for measuring the gas temperature in the processing chamber; and
an unit for controlling regulation of the temperature of the ring-shaped member on the basis of a gas temperature distribution in the processed surface of the sample to be processed which is obtained from measured gas temperatures;
wherein a hole through which a plasma radiation monitor gathers emission from the plasma so as to measure the gas temperature in the processing chamber is provided in the vicinity of the perimeter of the shower plate.

3. A plasma processing apparatus comprising: a processing chamber in which a sample to be processed is processed in a plasma; gas feeding means for feeding a processing gas to the processing chamber; exhausting means for depressurizing the processing chamber; a high-frequency power supply for plasma generation; a sample placement electrode on which the sample to be processed is placed; and an upper electrode opposed to the sample placement electrode, the gas feeding means including a shower plate disposed on the upper electrode,
the plasma processing apparatus further comprising:
means for measuring the gas temperature in the processing chamber;
means for measuring the radiation intensity of the plasma in the processing chamber;
a ring-shaped member that is disposed on the perimeter of the sample to be processed and has the temperature thereof regulated;
an unit for controlling regulation of the temperature of the ring-shaped member on the basis of a gas temperature distribution in the processing chamber which is obtained from measured gas temperatures;
a magnetic field strength distribution regulation means for regulating a magnetic field strength distribution in the processing chamber on the basis of the radiation intensity distribution in the processing chamber obtained from measured plasma radiation intensities; and
a feed gas composition regulation means for regulating the composition of a processing gas, which is fed to the processing chamber, on the basis of a radiation intensity distribution of free radicals in the processing chamber which is obtained from measured plasma radiation intensities.

4. The plasma processing apparatus according to claim 1, further comprising:
means for feeding a helium gas, which is used to cool a focus ring, to the back of the focus ring serving as the ring-shaped member; and
means for regulating the temperature of the focus ring by controlling the pressure of the helium gas on the basis of the gas temperature distribution.

5. The plasma processing apparatus according to claim 1, further comprising:
means for calculating the rotational temperatures of gas molecules in the processing chamber using the spectrum of plasma radiation gathered by the plasma radiation monitor, as the means for measuring the gas temperatures in the processing chamber.

6. The plasma processing apparatus according to claim 5,
wherein the means for calculating the rotational temperatures of gas molecules including:
a measurement data holding unit that holds in memory measurement data items that are measured in the processing chamber by the plasma radiation monitor and plotted into a spectral profile;
a spectral profile database in which data items to be plotted into spectral profiles associated with rotational temperatures of molecules of a gas to be used for rotational temperature measurement which are calculated in advance are preserved; and
a rotational temperature estimation unit that estimates the rotational temperature of gas molecules through comparison of the measured values plotted into the spectral profile with the data items plotted into the spectral profiles.

7. The plasma processing apparatus according to claim 2,
wherein at least one hole through which the plasma radiation monitor that measures the gas temperature gathers emission from plasma is a plurality of holes formed at positions on the shower plate in the radial directions of the sample to be processed.

8. The plasma processing apparatus according to claim 2, further comprising:
a focus ring that serves as the ring-shaped member; and
a shower plate that serves as part of the gas feeding means,
wherein: the width of the focus ring is 3 cm or more; and
the diameter of the shower plate is larger than the diameter of the sample to be processed by 6 cm or more.

9. The plasma processing apparatus according to claim 3, further comprising a focus ring that serves as the ring-shaped member,
wherein the uniformities in a gas temperature distribution, a plasma density distribution, and a radical density distribution in the processing chamber are regulated in order to bring etched profiles in the surface of the sample to be processed to uniformity.

10. The plasma processing apparatus according to claim 3,
wherein a gas temperature distribution in the processing chamber obtained by the unit for controlling regulation of the temperature of the ring-shaped member, a plasma density distribution in the processing chamber obtained by the magnetic field strength distribution regulation means, and a radical radiation intensity distribution in the processing chamber obtained by the feed gas composition regulation means are made uniform within respective ranges of predetermined values.
